(19) United States
(12) Patent Application Publication
(10) Pub. No.: US 2008/0298025 A1
(43) Pub. Date: Dec. 4, 2008

(54) SLIDING COVER MECHANISM OF PORTABLE ELECTRONIC DEVICE

(75) Inventors: CHENG-LUNG CHANG, Jen Te (TW); MEI-TSU TSAO, Jen Te (TW); PING-CHOU CHEN, Jen Te (TW)

Correspondence Address: PCE INDUSTRY, INC.;ATT. CHENG-JU CHIANG, 458 E. LAMBERT ROAD, FULLERTON, CA, 92835, US

(73) Assignee: CHI MEI COMMUNICATION SYSTEMS, INC., Tainan County (TW)

(21) Appl. No.: 11/860,500

(22) Filed: Sep. 24, 2007

(30) Foreign Application Priority Data
Jun. 1, 2007 (CN) 200710074697.7

(51) Int. Cl. H05K 5/03

(52) U.S. Cl. 361/727

(57) ABSTRACT

A sliding cover mechanism (100) includes a static member (10), a sliding member (20) and a flexible circuit board (60). The static member includes a receiving portion (101). The sliding member is movably mounted on the static member. One end of the flexible circuit board is mounted on the static member and another end of the flexible circuit board is mounted on the sliding member. The flexible circuit board is transformed and partly received in the receiving portion when the sliding member is moved on the static member.

### BACKGROUND OF THE INVENTION

1. Field of the Invention

The present invention relates to sliding cover mechanisms of portable electronic devices, and, particularly, to a sliding cover mechanism that can improve connecting quality of portable electronic devices.

2. Description of Related Art

Sliding cover mechanisms are widely used in portable electronic devices, such as mobile phones and personal digital assistants (PDAs). Referring to FIG. 1, a typical sliding cover mechanism generally includes a static member 91 and a sliding member 92. The static member 91 and the sliding member 92 are both approximately rectangular boards. Two opposite sides (not labeled) of the sliding member 92 extend to a same direction approximately perpendicular to the sliding member 92, and then bend towards each other, thus two receiving grooves (not labeled) are formed between the extending sides and the sliding member 92. Two opposite sides (not labeled) of the static member 91 respectively engage with the receiving grooves, thus the sliding member 92 is movably mounted on the static member 91. The sliding member 92 defines a hole 921 in its central portion.

In use, the static member 91 is mounted to a base (not shown) of a portable electronic device (not shown), and the sliding member 92 is mounted to a cover (not shown) of the portable electronic device. A flexible circuit board 93 is used to electronically connect the base and the cover. The flexible circuit board 93 has a rectangular shape, and a width thereof is less than that of the hole 921. One end of the flexible circuit board 93 is connected to the base, and the other end extending through the hole 921 of the sliding member 92 is connected to the cover. In use, the cover may be manually operated to slide on the base, i.e., the sliding member 92 may be driven by the cover to slide on the static member 91. The flexible circuit board 93 slides in the hole 921 to adapt its shape to changing positions of the sliding cover.

However, since space between the static member 91 and the sliding member 92 is usually very small, when the flexible circuit board 93 slides, it may be blocked or distorted between the static member 91 and the sliding member 92. Thus, the sliding cover mechanism cannot be normally operated, and the flexible circuit board 93 may be damaged.

Therefore, a new sliding cover mechanism of portable electronic devices is desired in order to overcome the above-described shortcomings.

### SUMMARY

A sliding cover mechanism includes a static member, a sliding member and a flexible circuit board. The static member includes a receiving portion. The sliding member is movably mounted on the static member. One end of the flexible circuit board is mounted on the static member and another end of the flexible circuit board is mounted on the sliding member. The flexible circuit board is transformed and partly received in the receiving portion when the sliding member is moved on the static member.

Other advantages and novel features will become more apparent from the following detailed description when taken in conjunction with the accompanying drawings.

### BRIEF DESCRIPTION OF THE DRAWINGS

Many aspects of the present sliding cover mechanism can be better understood with reference to the following drawings. The components in the various drawings are not necessarily drawn to scale, the emphasis instead being placed upon clearly illustrating the principles of the present sliding cover mechanism. Moreover, in the drawings, like reference numerals designate corresponding parts throughout the figures.

FIG. 1 is a schematic view of a typical sliding cover mechanism;

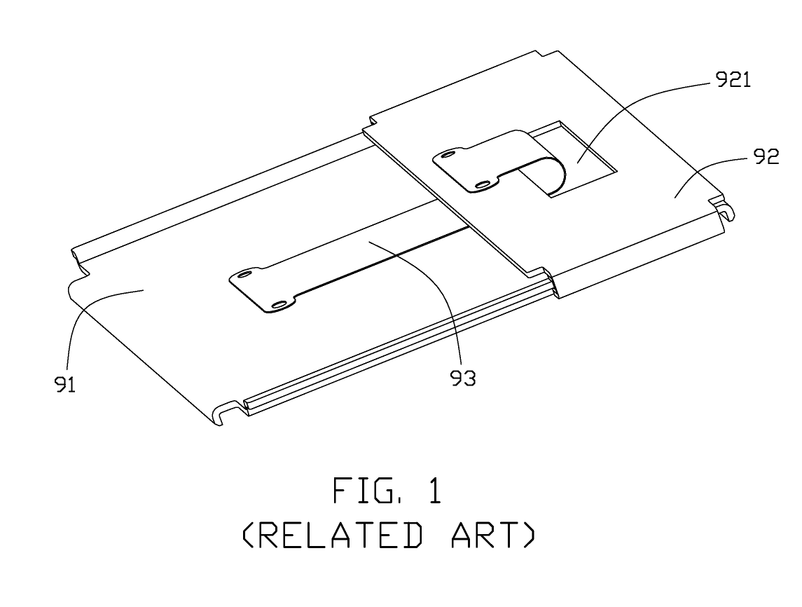

FIG. 2 is a closed, schematic view in a first visual angle of a sliding cover mechanism in accordance with a present embodiment;

FIG. 3 is similar to FIG. 2, but shown in a second visual angle;

FIG. 4 is a schematic view of a cover the portable electronic device mounted to the base of the portable electronic device via the sliding cover mechanism shown in FIG. 2;

FIG. 5 is a schematic view of a static member of the sliding cover mechanism shown in FIG. 2;

FIG. 6 is a schematic view of a sliding member of the sliding cover mechanism shown in FIG. 2;

FIG. 7 is an opened, schematic view in the first visual angle of the sliding cover mechanism shown in FIG. 2;

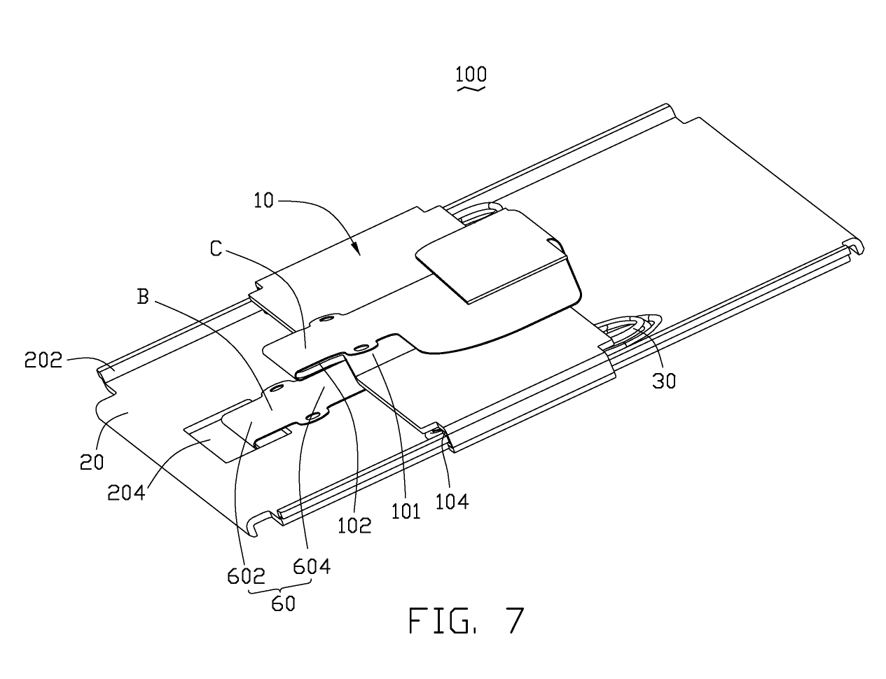

FIG. 8 is similar to FIG. 7, but shown in a second visual angle; and

FIG. 9 is a partly exploded view of a portable electronic device using the sliding cover mechanism in accordance with the present embodiment.

### DETAILED DESCRIPTION OF THE INVENTION

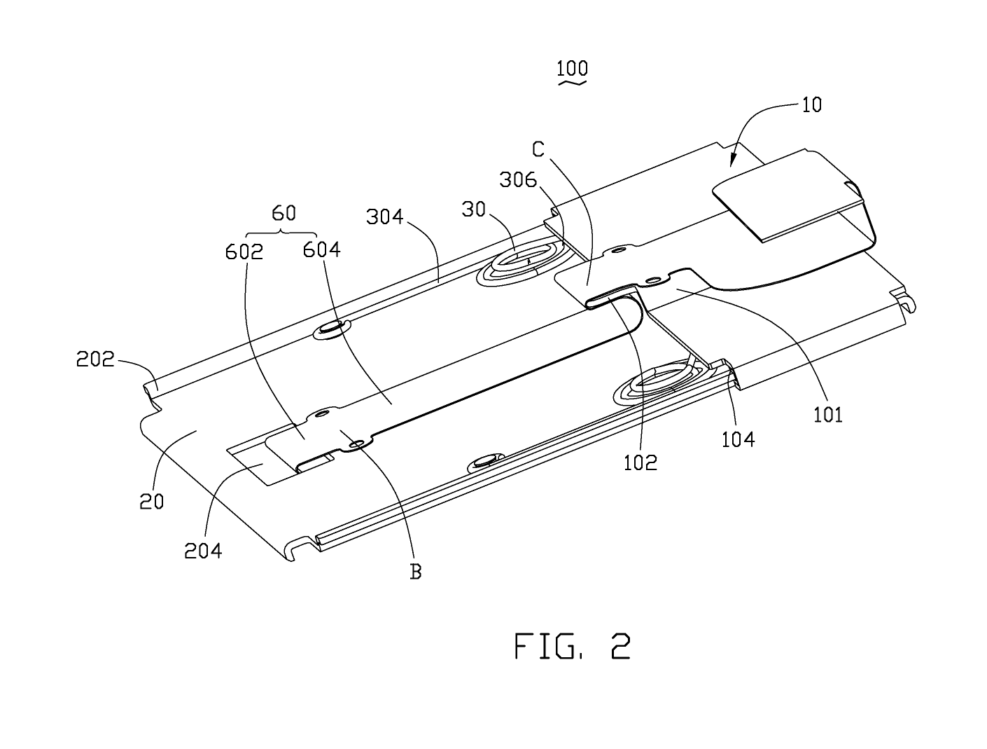

Referring to FIG. 2, a sliding cover mechanism 100 in accordance with a present embodiment is provided. The sliding cover mechanism 100 includes a static member 10, a sliding member 20, two resilient members 30 and a flexible circuit board 60. The sliding member 20 is movably mounted on the static member 10. The resilient members 30 are configured to resume the moved sliding member 20 to its initial position.

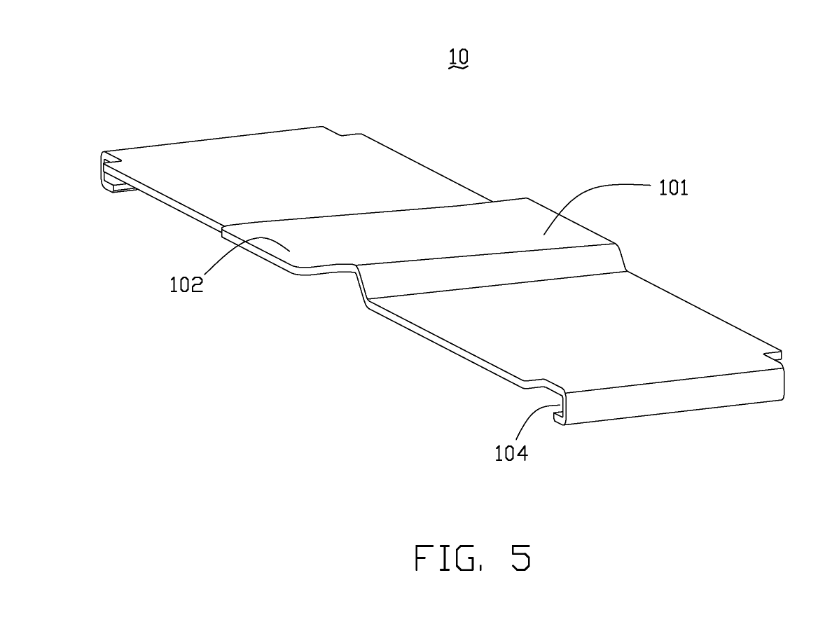

Also referring to FIG. 5, the static member 10 is approximately a rectangular board. A middle portion of static member 10 bends to form an approximately U-shaped receiving portion 101. One side of the receiving portion 101 extends to form an approximately rectangular mounting portion 102. Two opposite sides of the static member 10 bend to be approximately U-shaped, thereby forming two sliding grooves 104 opposite to each other.

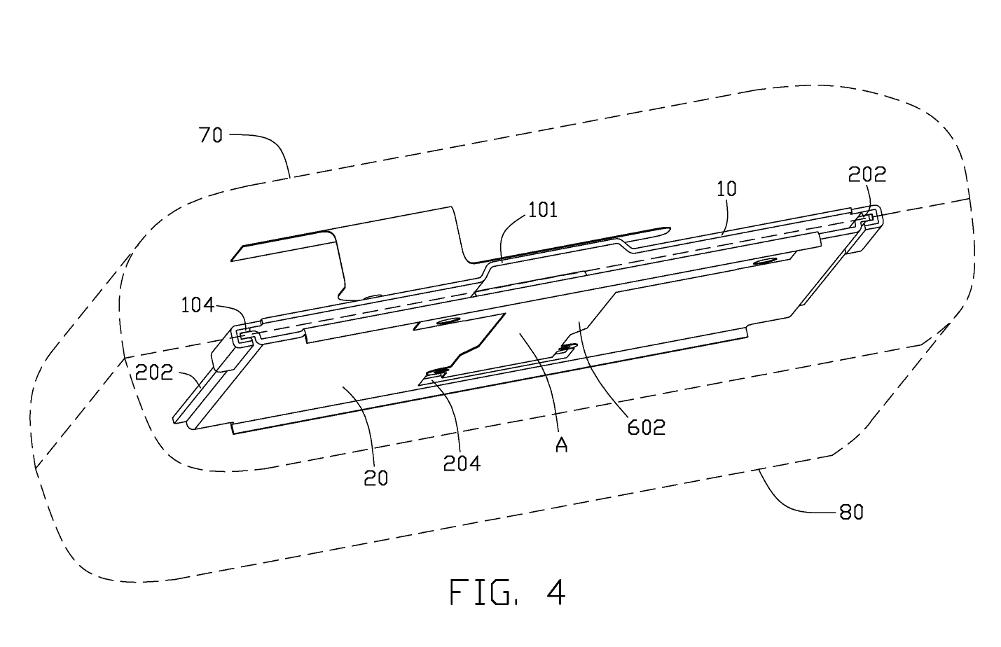

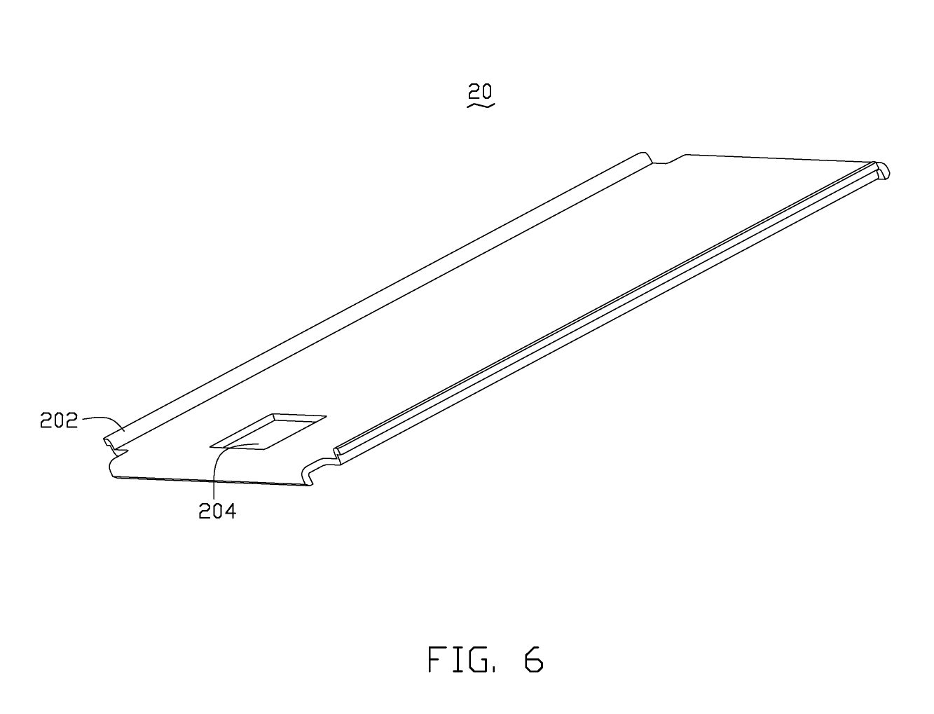

Also referring to FIG. 6, the sliding member 20 is an approximately rectangular board. Two opposite sides of the sliding member 20 extend along a same direction approximately perpendicular to the sliding member 20, and then bend away from each other. Thus, two sliding rails 202 corresponding to the sliding grooves 104 are respectively formed at two sides of the sliding member 20. Each sliding rail 202 movably engages with a corresponding sliding groove 104, particularly shown in FIG. 4. The sliding member 20 defines an approximately rectangular through hole 204 therein.

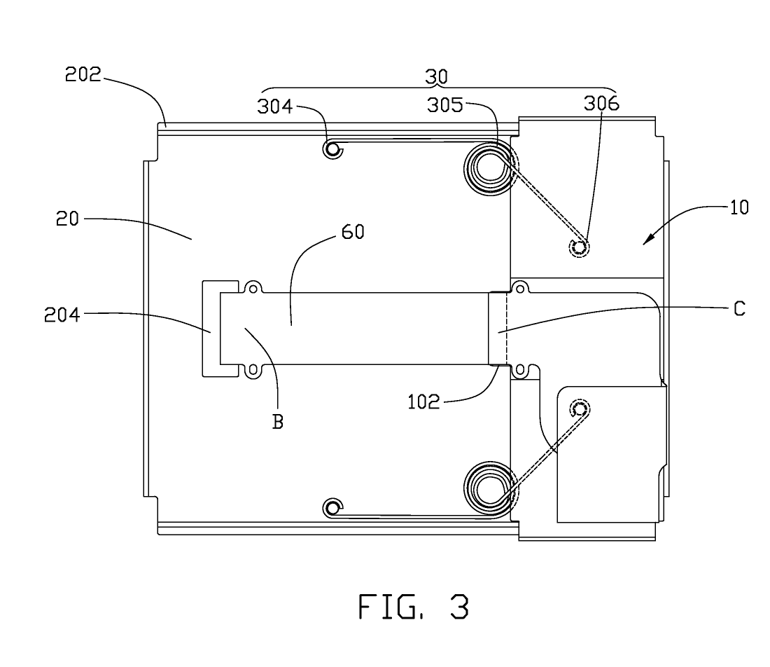

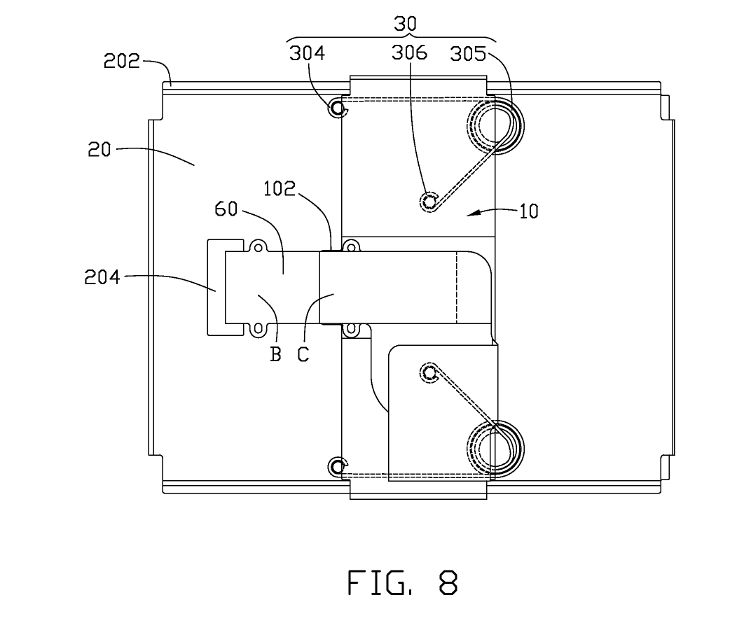

Also referring to FIG. 3 and FIG. 8, the resilient members 30 are two coiled springs. Each resilient member 30 includes a first fixed end 304, a resilient portion 305 and a second fixed end 306. The first fixed ends 304 of the resilient members 30 are respectively mounted on two sides adjacent to the sliding rails 202 of the sliding member 20. The resilient portion 305 of each resilient member 30 is coiled approximately parallel to the sliding member 20. The second fixed ends 306 of the resilient members 30 are mounted on a surface of the static member 10 which faces the sliding member 20.

Also referring to FIG. 2 and FIG. 4, the flexible circuit board 60 has a rectangular shape, and a width thereof is less than that of the through hole 204. The flexible circuit board 60 includes a first section 602 and a second section 604. The first section 602 includes a first mounting end A and a second mounting end B. The first mounting end A is fixedly mounted on a surface of the sliding member 20 while the second mounting end B is fixedly mounted on an opposite surface of the sliding member 20 which faces the static portion 10. The second section 604 is detachably mounted on the sliding member 20 and connected to the second mounting end B. The second section 604 includes a third mounting end C. The second section 604 is connected to the first section 602 via the second mounting end B. The second section 604 extends a distance away from the second mounting end B, and then retraces and the third mounting end C thereof is firmly mounted on the surface of the mounting portion 102 of the static member 10, thereby surrounding the mounting portion 102 as particularly shown in FIG. 2.

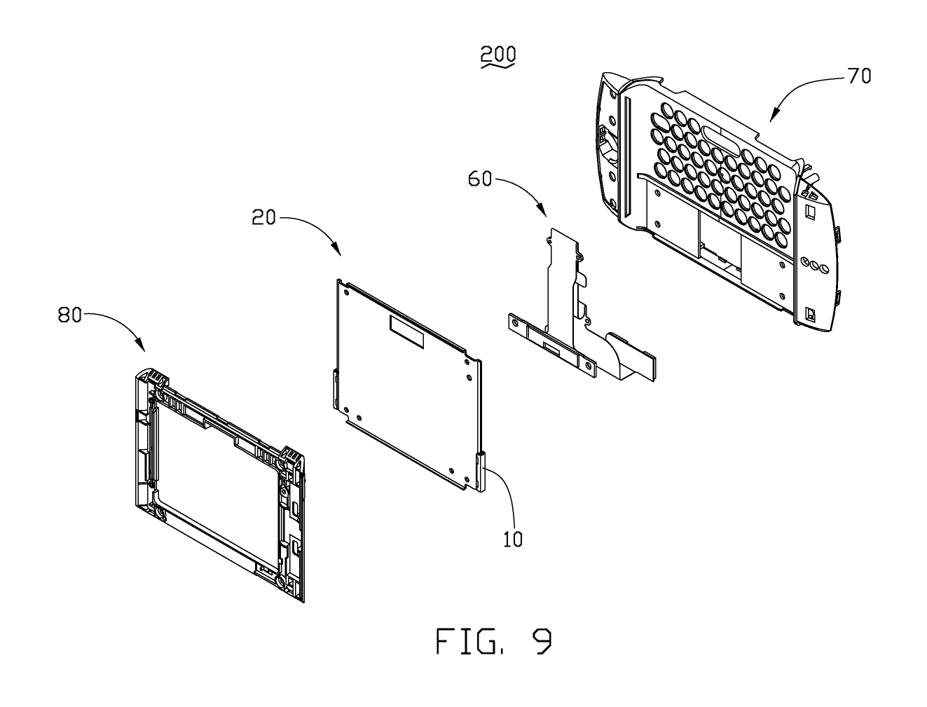

Also referring to FIG. 4 and FIG. 9, the sliding cover mechanism 100 is mounted on a portable electronic device 200 in accordance with a present embodiment. The portable electronic device 200 can be a mobile phone, a personal digital assistant (PDA), etc. The portable electronic device 200 includes a base 70 and a cover 80, and the cover 80 is movably mounted on the base 70 via the sliding cover mechanism 100.

In assembly, the static member 10 is mounted on the base 70 and electronically connected to the base 70, and the sliding member 20 is mounted on the cover 80 and electronically connected to the cover 80. In this way, the base 70 and the cover 80 are electronically connected to each other via the flexible circuit board 60. Each sliding rail 202 engages with a sliding groove 104 respectively, thus the sliding member 20 is movably mounted on the static member 10. The second surface 102 of the static member 10 is mounted towards the sliding rails 202, and mounting portion 1012 is mounted to extend towards the through hole 204. In this way, the sliding member 20 is movably mounted on the static member 10 and can slide along the sliding grooves 104, thus the cover 80 can slides on the base 70. Additionally, for decreasing a friction between the static member 10 and the sliding member 20, a filling (not labeled) made of a material having a small frictional coefficient such as plastic can be filled into the sliding grooves 104 for the sliding grooves 202 to engage with the sliding grooves 104.

In use, when the portable electronic device 200 is closed, the components of the sliding cover mechanism 100 are in the states shown in FIG. 2 and FIG. 3. When the portable electronic device 200 is opened, the sliding member 20 slides on the static member 10 along the sliding grooves 104, thus the cover 80 slides on the base 70. At the same time, the second mounting end B of the flexible circuit board 60 moves towards the static member 10 and the third mounting end C, thereby forcing the second section 604 to detach from the sliding member 20 and gradually enter the receiving portion 101 until most of the second section 604 is received in the receiving portion 101. In this way, the flexible circuit board 60 moves and transforms in a predetermined space defined between the receiving portion 101 and a portion of the sliding member 20 which faces the receiving portion 101, thus the flexible circuit board 60 will not block movement of the sliding member 20 when the sliding member 20 is moved with respect to the static member 10.

Also referring to FIG. 3 and FIG. 8, when the sliding member 20 slides along the sliding grooves 104, the resilient members 30 is bent and stores potential energy. When the cover 80 slides to a predetermined opened position, a typical retainer (not shown) mounted in the portable electronic device 200 retains the sliding member 20, thus the portable electronic device 200 can be used. When the portable electronic device 200 closes, the retainer is released, and the resilient members 30 release the stored potential energy and resume to initial shapes. Thus, the sliding member 20 and the cover 80 are driven to initial positions, which close the portable electronic device 200.

Additionally, the flexible circuit board 60 can be mounted on the static member 10 and the sliding member 20 via gluing, soldering or bolting, etc. Either one of the resilient members 30 can be omitted.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A sliding cover mechanism, comprising:
a static member, the static member including a receiving portion;
a sliding member movably mounted on the static member; and
a flexible circuit board, one end of the flexible circuit board being mounted on the static member and another end of the flexible circuit board being mounted on the sliding member; the flexible circuit board being transformed and partly received in the receiving portion when the sliding member is moved on the static member.

2. The sliding cover mechanism as claimed in claim 1, wherein the static member is a rectangular board, and a middle portion of the static member bends to form the receiving portion.

3. The sliding cover mechanism as claimed in claim 2, wherein a side of the receiving portion extends to form a mounting portion.

4. The sliding cover mechanism as claimed in claim 3, wherein the static member comprises two sliding grooves formed at two opposite sides thereof; and wherein the sliding member is a rectangular board comprising two sliding rails formed at two opposite sides thereof and corresponding to the sliding grooves respectively, each sliding rail being movably engaged with a corresponding one of the sliding grooves.

5. The sliding cover mechanism as claimed in claim 3, wherein the sliding member defines a through hole therein.

6. The sliding cover mechanism as claimed in claim 5, wherein the flexible circuit board includes a first section, one end of the first section is mounted on a surface of the sliding member against the static member, and another end of the first section runs through the through hole and is mounted on another surface of the sliding member which faces the static member.

7. The sliding cover mechanism as claimed in claim 6, wherein the flexible circuit board includes a second section, the second section is detachably mounted on the surface of the sliding member which faces the static member, one end of the second section is connected to the first section, and another end of the second section is mounted on the static member.

8. The sliding cover mechanism as claimed in claim 7, wherein an end of the second section is mounted on the mounting portion.

9. A portable electronic device, comprising:
a base;
a cover; and
a sliding cover mechanism, the cover being movably mounted on the base and electronically connected to the base via the sliding cover mechanism; the sliding cover mechanism including a static member defining a receiving portion therein, a sliding member movably mounted on the static member and a flexible circuit board electronically connected the static member to the sliding member; the flexible circuit board being partly received in the receiving portion once the sliding member moves on the static member.

10. The portable electronic device as claimed in claim 9, wherein one end of the flexible circuit board is mounted on the static member and another end of the flexible circuit board is mounted on the sliding member.

11. The portable electronic device as claimed in claim 9, wherein the static member is mounted on the base, and the sliding member is mounted on the cover.

12. The portable electronic device as claimed in claim 9, wherein the static member comprises two sliding grooves formed at two opposite sides thereof; and wherein the sliding member is a rectangular board comprising two sliding rails corresponding to the sliding grooves respectively formed at two opposite sides thereof, each sliding rail being movably engaged with a corresponding one of the sliding grooves.

13. The portable electronic device as claimed in claim 9, wherein the sliding member defines a through hole therein.

14. The portable electronic device as claimed in claim 13, wherein the flexible circuit board includes a first section, one end of the first section is mounted on a surface of the sliding member against the static member, and another end of the first section runs through the through hole and is mounted on another surface of the sliding member which faces the static member.

15. The portable electronic device as claimed in claim 14, wherein the flexible circuit board includes a second section, the second section is detachably mounted on the surface of the sliding member which faces the static member, one end of the second section is connected to the first section, and another end of the second section is mounted on the static member.
